(19) United States
(12) Patent Application Publication
(10) Pub. No.: US 2003/0213991 A1
(43) Pub. Date: Nov. 20, 2003

(54) Flash memory cell

(76) Inventors: Hee Youl Lee, Ichon-Shi (KR); Soo Min Cho, Seoul (KR)

Correspondence Address: Jacobson Holman, Professional Limited Liability Company, 400 Seventh Street, N. W., Washington, DC, 20004-2218, US

(21) Appl. No.: 10/310,146

(22) Filed: Dec. 5, 2002

(30) Foreign Application Priority Data
May 17, 2002 (KR) 2002-27477

(51) Int. Cl. H01L 29/788

(52) U.S. Cl. 257/316

(57) ABSTRACT

The present invention relates to a flash memory cell. The type and concentration of an impurity injected into a floating gate and a polysilicon layer for a control gate is controlled so that upon an erase operation, as a threshold voltage is reduced, a depletion layer is formed in a first polysilicon layer, discharge of electrons is increasingly reduced as the threshold voltage reaches a target voltage and discharge of the electrons is stopped at the target voltage. Therefore, over erase of the flash memory cell is prevented. Malfunction of the cell due to over erase is prevented and reliability and an electrical characteristic of the erase operation can be improved by distributing threshold voltages of all the cells to target voltages.

### BACKGROUND OF THE INVENTION

1. Field of the Invention

The invention relates generally to a flash memory cell, and more particularly to, a flash memory cell capable of prohibiting generation of over-erase upon an erase operation.

2. Description of the Prior Art

Generally, a flash memory cell consists of a tunnel oxide film, a floating gate, a dielectric film, a control gate, and source/drain. The threshold voltage of the flash memory cell is changed depending on the degree that electrons are trapped in the floating gate by a program operation or an erase operation. Upon a read operation, the amount of a drain current flowing into the cell is varied depending on the threshold voltage of the cell. Data stored at the flash memory cell is sorted as ‘1’ and ‘0’, depending on the amount of the drain current.

FIG. 1A and FIG. 1B are graphs illustrating variation in the threshold voltage of the flash memory cell depending on the program operation and the erase operation.

Referring now to FIG. 1A, if the program operation is performed, the threshold voltage of the flash memory cell is increased from 1 through 3V to 6 through 8V. If the threshold voltage of the cell is increased, the drain current does not flow even though a read voltage is applied to the control gate. This state is called a program state that data of ‘0’ is stored at the flash memory cell.

By reference to FIG. 1B, if the erase operation is performed, the threshold voltage of the flash memory cell is decreased from 6 through 8V to 1 through 3V. If the read voltage is applied to the control gate in a state that the threshold voltage of the cell is lowered, the drain current flows. This state is called an erase state that data of ‘1’ is stored at the flash memory cell.

As described above, the program operation is one by which the threshold voltage of the cell is raised so that the drain current does not flow into the flash memory cell upon the read operation. Therefore, only if the threshold voltage of the cell is higher than a specific voltage so that the drain current does not flow even though the read voltage is applied, there occurs nothing problem in the cell.

Meanwhile, the erase operation is one by which the threshold voltage of the cell is lowered so that a given drain current can flow into the flash memory cell upon the read operation. However, the erase operation must be performed so that the threshold voltage can maintain a constant level even though the threshold voltage of the cell is lowered. In other words, if the threshold voltage of the cell is too low since the erase operation is excessively performed (hereinafter called ‘over-erase’), there occurs an electrical problem in the cell since the drain current flows even though the read voltage is not applied to the cell.

FIG. 2 is a drawing for explaining a structure of the flash memory cell and the coupling capacitance.

Referring now to FIG. 2, the flash memory cell basically includes a tunnel oxide film (not shown), a floating gate 201 made of a first polysilicon layer, a dielectric film (not shown), a control gate 202 having a second polysilicon layer and a silicide layer, and source/drain 203a and 203b formed in the semiconductor substrate 200 at both sides of the floating gate 201, all of which are sequentially stacked on a semiconductor substrate 200.

The flash memory cell constructed above is called a stack gate type flash memory cell. The erase operation is performed by which electrons trapped at the floating gate 201 by an electric field generating due to the difference in the potential between the floating gate 201 and the substrate 200 are erased by means of a F-N (Fowler-Nordheim) tunneling scheme.

The potential (Vfg) of the floating gate 201 to which a bias could not be directly applied is determined by the potential induced by a coupling capacitance ratio formed among the control gate 202, the substrate 200 and the source/drain 203a and 203b, and the floating gate 201, and the amount of a self charge, as in Equation 1 below.

Vfg=Kfc×Vg+Kd×Vd+Ks×Vs+Kb×Vb+Kfc(Vtuv−Vtcell)

Ct=Cfc+Cd+Cs+Cb

Kfc=(Cfc/Ct),Kd=(Cd/Ct),Ks=(Cs/Ct),Kb=(Cb/Ct)

Kfc+Kd+Ks+Kb=1 [Equation 1]

In Equation 1, ‘Vtuv’ indicates the threshold voltage at an equilibrium state and ‘Vtcell’ indicates the threshold voltage at a current state. Also, ‘Kfc’ is the coupling ratio of the dielectric film, ‘Kd’ is the coupling ratio of the drain, ‘Ks’ is the coupling ratio of the source and ‘Kb’ is the coupling ratio of the substrate.

As in FIG. 2 and Equation 1, the thickness and area of the dielectric material existing between the floating gate 201 and other components greatly affect formation of the potential of the floating gate 201.

The erase operation is performed by which a negative bias is applied to the control gate 202 and a positive bias is applied to the substrate 200. Usually, in order to keep the coupling capacitance ratio of about 0.6 and the coupling ratio of about 0.4 pt between the substrate 200 including the source/drain 203a and 203b region and the floating gate 201 while the electrons are not moved between the control gate 202 and the floating gate 201, it is required that the thickness of the dielectric film between the control gate 202 and the floating gate 201 be relatively thicker than that of the tunnel oxide film between the floating gate 201 and the semiconductor substrate 200.

At this time, if about 7.0 V is applied to the threshold voltage of the cell, − a bias of about −6V is applied to the control gate 202 and a bias of about 8.0V is applied to the substrate, the potential of the floating gate 201 is about −2.8V. Also, if the potential difference applied to the tunnel oxide film is 10.8V and the thickness of the tunnel oxide film is 8 nm, an electric field of about 13MV/cm is formed. The electrons are discharged from the floating gate 201 by means of the F-N tunneling. If the threshold voltage of the cell becomes 2V, the potential of the floating gate 201 becomes about 0.2V and the electric field becomes about 9.7 MV/cm.

The F-N tunneling current is exponentially increased against the electric field, as in Equation 2 below.

J=A×E²exp(−B/E) [Equation 2]

In the above, ‘J’ is a tunneling current density, ‘A’ and ‘B’ are constants and ‘E’ is the intensity of the electric field.

If the erase operation time becomes longer, over erase is performed. The threshold voltage of the cell may be lowered below 0V. If over-erase happens, malfunction of the circuit or defective circuit may happen.

FIG. 3 is a circuit diagram of the flash memory cell for explaining a case where malfunction is generated due to an over-erased cell.

Referring now to FIG. 3, drains of a plurality of flash memory cells C301, C302, . . . , C30n are commonly connected to a bit line BL. The flash memory cells C301, C302, . . . , C30n are selected by an address signal applied to word lines WL301, WL302, . . . , WL30n. At this time, an example in which the first flash memory cell C301 is at a program state, the second flash memory cell C302 is at an over-erase state and the third flash memory cell C30n is at a normal erase state will be below described.

For example, if the read voltage is applied to a control gate of the first flash memory cell C301 through the first word line WL301 in order to read data stored at the first flash memory cell C301, the drain current does not flow into the first flash memory cell C301 as the threshold voltage is high even though the read voltage is applied since the first flash memory cell C301 is at the program state. Meanwhile, the drain current does not also flow into the second and third flash memory cells C302 and C30n since the read voltage is not applied to the second and third flash memory cells C302 and C30n. Therefore, the amount of the drain current detected through the bit line BL is 0A. It is also determined that data stored at the first flash memory cell C301 is ‘0’.

However, as the second flash memory cell C302 is over erased, the drain current (I) flows into the second flash memory cell C302 even though the read voltage is not applied, which is detected through the bit line BL. Therefore, data stored at the first flash memory cell C301 is ‘0’. However, data stored at the first flash memory cell C301 is determined to be ‘1’ by means of the drain current (I) flowing into the over-erased second flash memory cell C302. Due to this, an error occurs.

In order to solve this problem, a post program is performed in order to raise the threshold voltage of the over-erase cell to a target voltage after the erase operation is performed. However, even though the post program is performed, there may exist the over-erased cells the threshold voltages of which are not raised to the target voltages. Accordingly, there are problems that reliability by the post program is not high and there is a possibility of malfunction.

### SUMMARY OF THE INVENTION

The present invention is contrived to solve the above problems and an object of the present invention is to provide a flash memory cell, capable of preventing over erase of the flash memory cell, and preventing malfunction of the cell due to over erase and improving reliability and an electrical characteristic of an erase operation, by distributing threshold voltages of all the cells to target voltages. For this, the type and concentration of an impurity injected into a floating gate and a polysilicon layer for a control gate is controlled, so that upon an erase operation, as a threshold voltage is reduced, discharge of electrons is increasingly reduced while a depletion layer is formed in a first polysilicon layer and discharge of the electrons is then stopped at the target voltage as the threshold voltage reaches a target voltage.

In order to accomplish the above object, the flash memory according to a first embodiment of the present invention, is characterized in that it comprises a tunnel oxide film formed on a semiconductor substrate, a first polysilicon layer into which an impurity is doped, wherein the first polysilicon layer is formed on the tunnel oxide film, a dielectric film formed on the first polysilicon layer, a second polysilicon layer into which an impurity is doped, wherein the second polysilicon layer is formed on the dielectric film, and source/drain formed in the semiconductor substrate at both sides of the first polysilicon layer, wherein a doping concentration of the first polysilicon layer is set to be lower than a doping concentration of the second polysilicon layer so that upon an erase operation, as a threshold voltage is reduced, discharge of electrons is reduced while a depletion layer is formed in the first polysilicon layer and discharge of the electrons is then stopped at a target voltage.

At this time, the impurity is arsenic (As) or phosphorous (P), the doping concentration of the first polysilicon layer is 1.0E19 through 1.2E20/cm³ and the doping concentration of the second polysilicon layer is 2.0E20 through 4.0E20/cm³.

The flash memory according to a second embodiment of the present invention, is characterized in that it comprises a tunnel oxide film formed on a semiconductor substrate, a first polysilicon layer into which an impurity is doped, wherein the first polysilicon layer is formed on the tunnel oxide film, a dielectric film formed on the first polysilicon layer, a second polysilicon layer into which an impurity of a type opposite to the impurity doped into the first polysilicon layer is doped, wherein the second polysilicon layer is formed on the dielectric film, a silicide layer formed on the second polysilicon layer, and source/drain formed in the semiconductor substrate at both sides of the first polysilicon layer, wherein the type of the impurity doped into the first and second polysilicon layers is set so that upon an erase operation, as a threshold voltage is reduced, discharge of electrons is reduced while a depletion layer is formed in the first polysilicon layer and discharge of electrons is then stopped at a target voltage.

At this time, the impurity injected into the first polysilicon layer is an N type impurity and the impurity injected into the second polysilicon layer is a P type impurity.

In the above, the N type impurity is phosphorous (P) or arsenic (As) and has a doping concentration of 2.0E20 through 4.0E20/cm³. The P type impurity is boron (B) and has a doping concentration of 1.0E19 through 1.2E20/cm³.

The N type impurity is phosphorous (P) and has a doping concentration of 1.0E19 through 1.2E20/cm³. The P type impurity is boron (B) and has a doping concentration of 1.0E19 through 1.2E20/cm³.

The N type impurity is arsenic (As) and has a doping concentration of 1.0E19 through 1.0E20/cm³. The P type impurity is boron (B) and has a doping concentration of 1.0E19 through 1.2E20/cm³.

### BRIEF DESCRIPTION OF THE DRAWINGS

The aforementioned aspects and other features of the present invention will be explained in the following description, taken in conjunction with the accompanying drawings, wherein:

FIG. 1A and FIG. 1B are graphs illustrating variation in the threshold voltage of a flash memory cell depending on a program operation and an erase operation;

FIG. 2 is a drawing for explaining a structure of a flash memory cell and a coupling capacitance;

FIG. 3 is a circuit diagram of a flash memory cell for explaining a case where a malfunction is generated by an over-erased cell.

FIG. 4 is a cross sectional view of a flash memory cell for explaining a state that a depletion layer is generated in a floating gate as the potential of the floating gate is increased in a positive direction;

FIG. 5 is a graph illustrating a potential characteristic of the floating gate and a coupling capacitance characteristic between the floating gate and the control gate depending on a doping concentration of the floating gate; and

FIG. 6 is a graph illustrating the relationship between the threshold voltage of the floating gate and an erase time depending on the doping concentration of the floating gate.

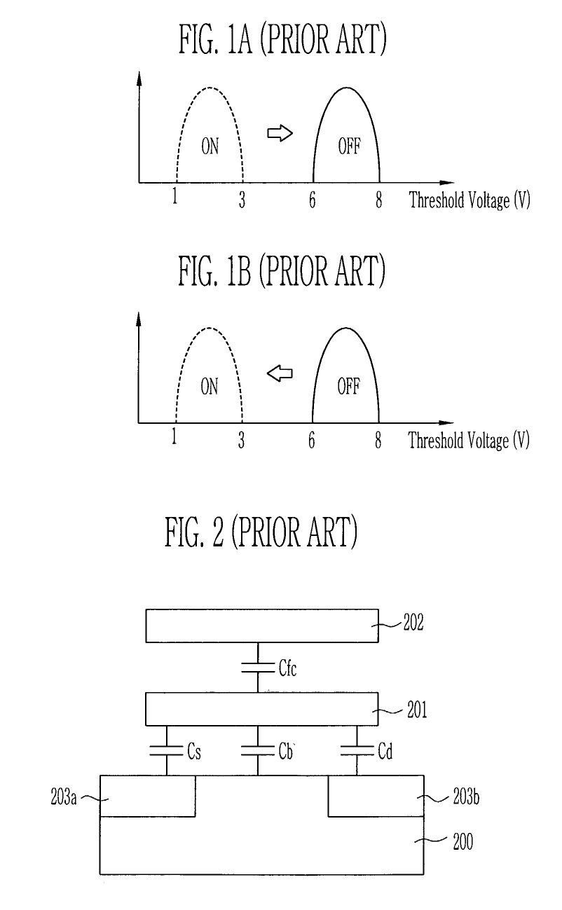

### DETAILED DESCRIPTION OF PREFERRED EMBODIMENTS

The present invention will be described in detail by way of a preferred embodiment with reference to accompanying drawings, in which like reference numerals are used to identify the same or similar parts.

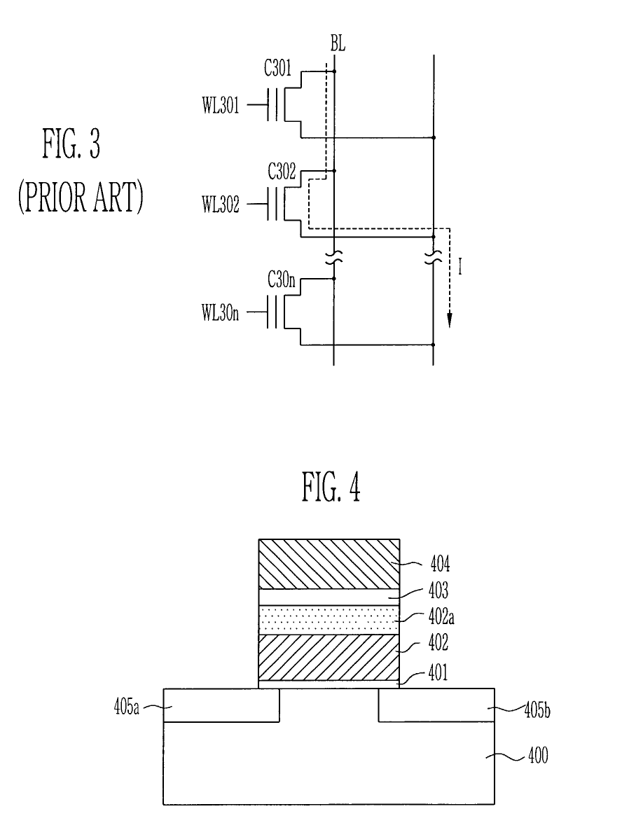

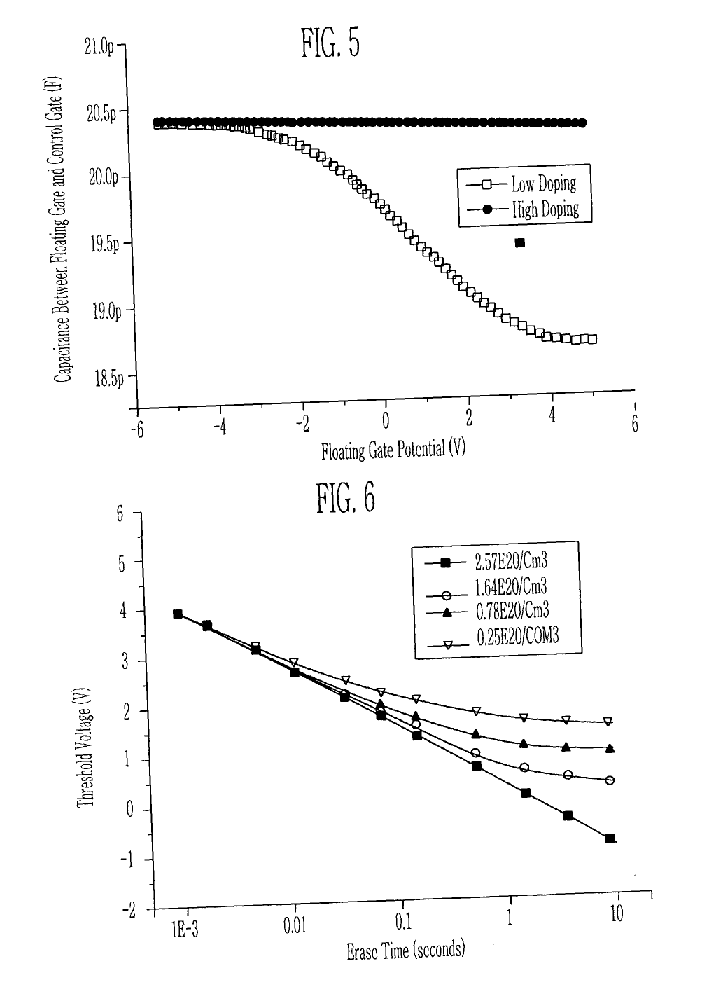

FIG. 4 is a cross sectional view of a flash memory cell for explaining a state that a depletion layer is generated in a floating gate as the potential of the floating gate is increased in a positive direction, and FIG. 5 is a graph illustrating a potential characteristic of the floating gate and a coupling capacitance characteristic between the floating gate and the control gate depending on a doping concentration of the floating gate.

If the coupling ratio applied to a dielectric film 403 is reduced in a process in which the threshold voltage of the cell is lowered upon an erase operation, the potential of a floating gate 402 is increased in a positive direction and an electric filed applied to a tunnel oxide film 401 is thus reduced. Thus, as movement of electrons by F-N tunneling is inhibited, it is possible to prevent lowering in the threshold voltage of the cell below a specific voltage.

For this, the type and amount of an impurity doped into the floating gate 402 and the control gate 404 are controlled. A method of controlling the type and amount of the impurity will be described in detail.

As a first embodiment, in case of a flash memory cell in which source/drain 405a and 405b are formed as a N type impurity region, a N type impurity of a low concentration is injected into a first polysilicon layer for the floating gate 402 and a N type impurity of a high concentration is injected into a second polysilicon layer for the control gate 404. In this case, arsenic (As) or phosphorous (P) having a concentration of 1.0E19 through 1.2E20/cm³ is doped into the first polysilicon layer for the floating gate 402. Meanwhile, arsenic (As) or phosphorous (P) having a concentration of 2.0E20 through 4.0E20/cm³ is doped into the second polysilicon layer for the control gate 404.

As a second embodiment, in case of the flash memory cell in which the source/drain 405a and 405b are formed as the N type impurity region, a N type impurity of a high concentration is injected into the first polysilicon layer for the floating gate 402 and the P type impurity of a low concentration is injected into the second polysilicon layer for the control gate 404. In this case, arsenic (As) or phosphorous (P) having a concentration of 2.0E20 through 4.0E20/cm³ is doped into the first polysilicon layer for the floating gate 402. Meanwhile, boron (B) having a concentration of 1.0E19 through 1.2E20/cm³ is doped into the second polysilicon layer for the control gate 404.

As a third embodiment, in case of the flash memory cell in which the source/drain 405a and 405b are formed as the N type impurity region, a N type impurity of a low concentration is injected into the first polysilicon layer for the floating gate 402 and the P type impurity of a low concentration is injected into the second polysilicon layer for the control gate 404. In this case, phosphorous (P) having a concentration of 1.0E19 through 1.2E20/cm³ or arsenic (As) having a concentration of 1.0E19 through 1.0E20/cm³ is doped into the first polysilicon layer for the floating gate 402. Meanwhile, boron (B) having a concentration of 1.0E19 through 1.2E20/cm³ is doped into the second polysilicon layer for the control gate 404.

If an erase operation is performed under the above conditions after the impurity is doped into the floating gate 402 and the control gate 404, the coupling ratio applied to the dielectric film is lowered in a process in which the threshold voltage is lowered upon the erase operation, so that the potential of the floating gate 402 is increased in a positive direction. Due to this, movement of the electrons by F-N tunneling is inhibited while the electric filed applied to the tunnel oxide film is reduced. It is thus possible to prevent lowering in the threshold voltage of the cell below a specific voltage.

The erase operation in which a negative bias is applied to the control gate 404 and a positive bias is applied to the semiconductor substrate 400 or the source 405a is performed. If the threshold voltage is lowered by the erase operation, the potential of the floating gate 402 is increased in the positive direction. Like the case that the depletion layer is formed in the substrate below the gate of the transistor, the depletion layer 402a is also formed on the floating gate 402 into which the N type impurity is doped. Due to this, the coupling capacitance between the floating gate 402 and the control gate 404 is reduced, as shown in FIG. 5.

FIG. 6 is a graph illustrating the relationship between the threshold voltage of the floating gate and an erase time depending on the doping concentration of the floating gate.

As shown in FIG. 6, in case that the concentration of the impurity doped into the floating gate is 0.25E20/cm³ through 1.64E20/cm³ in the first embodiment, it can be seen that as the threshold voltage reaches the target voltage, the F-N tunneling drain current is exponentially reduced while the electric field is reduced and the threshold voltage is then converged to a target voltage.

In more detail, if the impurity having a concentration of 2.57E20/cm³ is doped into the floating gate, it can be seen that during the erase operation, the threshold voltage is continuously lowered and is then lowered to below 0V, so that over erase is generated.

However, if the impurity having a concentration of 0.25E20/cm³ is doped into the floating gate, it can be seen that the threshold voltage is lowered and is then lowered to about 1.2V, where discharge of the electrons is stopped, and the threshold voltage is thus not further lowered and is converged to about 1.2V. In other words, regardless of the erase operation time, the threshold voltage of the cell becomes 1.2V.

Meanwhile, if the impurity having a concentration of 0.78E20/cm³ or 1.64E20/cm³ is doped into the floating gate, it can be seen that though the threshold voltage is converged to a voltage (0.3V through 0.7V) that is a little lower than that in the case where the impurity having a concentration of 0.25E20/cm³ is doped, the threshold voltage is not further lowered even though the erase operation is continuously performed and is then converged to a specific voltage.

If the concentration of the floating gate is too low, however, an inversion layer may be formed in the floating gate. Therefore, it is important to set the doping concentration of the floating gate to a degree that the depletion layer may be formed, depending on the process condition.

As mentioned above, the present invention, the present invention has an advantageous effect that it can prevent over erase of the flash memory upon the erase operation by controlling the type and concentration of the impurity doped into the floating gate and the control gate are controlled. Also, the present invention has advantageous effects that it can prevent malfunction of the device due to over-erase and improve reliability and an electrical characteristic of the erase operation, by converging the threshold voltage to a target voltage.

Further, a post program needs not be performed after the erase operation is performed. Thus, the present invention can improve the operating speed of the circuit since the erase operation time is reduced.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A flash memory cell, comprising:
a tunnel oxide film formed on a semiconductor substrate;
a first polysilicon layer into which an impurity is doped, wherein the first polysilicon layer is formed on the tunnel oxide film;
a dielectric film formed on the first polysilicon layer;
a second polysilicon layer into which an impurity is doped, wherein the second polysilicon layer is formed on the dielectric film; and
source/drain formed in the semiconductor substrate at both sides of the first polysilicon layer,
wherein a doping concentration of the first polysilicon layer is set to be lower than a doping concentration of the second polysilicon layer so that upon an erase operation, as a threshold voltage is reduced, discharge of electrons is reduced while a depletion layer is formed in the first polysilicon layer and discharge of the electrons is then stopped at a target voltage.

2. The flash memory cell as claimed in claim 1, wherein the impurity is arsenic or phosphorous.

3. The flash memory cell as claimed in claim 1, wherein the doping concentration of the first polysilicon layer is 1.0E19 through 1.2E20/cm³.

4. The flash memory cell as claimed in claim 1, wherein the doping concentration of the second polysilicon layer is 2.0E20 through 4.0E20/cm³.

5. A flash memory cell, comprising:
a tunnel oxide film formed on a semiconductor substrate;
a first polysilicon layer into which an impurity is doped, wherein the first polysilicon layer is formed on the tunnel oxide film;
a dielectric film formed on the first polysilicon layer;
a second polysilicon layer into which an impurity of a type opposite to the impurity doped into the first polysilicon layer is doped, wherein the second polysilicon layer is formed on the dielectric film;
a silicide layer formed on the second polysilicon layer; and
source/drain formed in the semiconductor substrate at both sides of the first polysilicon layer,
wherein the type of the impurity doped into the first and second polysilicon layers is set so that upon an erase operation, as a threshold voltage is reduced, discharge of electrons is reduced while a depletion layer is formed in the first polysilicon layer and discharge of electrons is then stopped at a target voltage.

6. The flash memory cell as claimed in claim 5, wherein the impurity doped into the first polysilicon layer is an N type impurity and the impurity doped into the second polysilicon layer is a P type impurity.

7. The flash memory cell as claimed in claim 6, wherein the N type impurity is phosphorous or arsenic and the doping concentration of the N type impurity is 2.0E20 through 4.0E20/cm³, and wherein the P type impurity is boron and the doping concentration of boron is 1.0E19 through 1.2E20/cm³.

8. The flash memory cell as claimed in claim 6, wherein the N type impurity is phosphorous and the doping concentration of phosphorous is 1.0E19 through 1.2E20/cm³, and wherein the P type impurity is boron and the doping concentration of boron is 1.0E19 through 1.2E20/cm³.

9. The flash memory cell as claimed in claim 6, wherein the N type impurity is arsenic and the doping concentration of arsenic is 1.0E19 through 1.0E20/cm³, and wherein the P type impurity is boron and the doping concentration of boron is 1.0E19 through 1.2E20/cm³.
